(19) United States
(12) Patent Application Publication
(10) Pub. No.: US 2026/0143933 A1
(43) Pub. Date: May 21, 2026

(54) DISPLAY SUBSTRATE AND DISPLAY DEVICE

(71) Applicant: BOE TECHNOLOGY GROUP CO. , LTD., Beijing (CN)

(72) Inventors: Ying HAN, Beijing (CN); Pan XU, Beijing (CN); Guangshuang LV, Beijing (CN); Cheng XU, Beijing (CN)

(21) Appl. No.: 18/706,131

(22) PCT Filed: Apr. 13, 2023
(86) PCT No.: PCT/CN2023/088024

§ 371 Date: Apr. 30, 2024

(51) Int. Cl. H10K 59/131; G09G 3/3233

(52) U.S. Cl. CPC H10K 59/131; G09G 3/3233

(57) ABSTRACT

A display substrate and a display device are provided, the display substrate includes a base substrate and conductive pads in a bonding region, each conductive pad includes a first sub-pad, a first insulating layer, a second sub-pad, a second insulating layer, a first via, and a second via. The second sub-pad is directly connected with the first sub-pad through the first via in the first insulating layer; the second via penetrates the second insulating layer to expose a part of the second sub-pad. At least one first via is provided between the first sub-pad and a corresponding second sub-pad, an orthographic projection of the first via on the base substrate overlaps with an orthographic projection of at least one second via on the base substrate, and at least one second via has a size in the second direction being larger than a size in the first direction.

### TECHNICAL FIELD

Embodiments of the present disclosure relate to a display substrate and a display device.

### BACKGROUND

The design of OLED (Organic Light Emitting Diode) display panel includes pixel design, gate driver on array (GOA) circuit design, packaging design, and other aspects. The OLED display panel includes a conductive pad (bonding pad) located in a bonding region, the bonding pad can be used as an input position of driving signals of the display panel, one end of a flexible printed circuit board (FPC) is connected with a driving circuit board, and the other end of the flexible printed circuit board is connected with the conductive pad in the bonding region, so that the driving circuit board can transmit display data to the display panel through the flexible printed circuit board to drive the display panel to perform light emitting display. For example, the flexible printed circuit board may be a chip on film (COF) with a chip thereon. Therefore, the design of the conductive pad will affect the connection between the flexible printed circuit board and the display panel, and then affect the display effect of the display panel. The conductive pad can be designed and adjusted according to different processes to achieve the best lapping connection effect and the best display effect of the display panel.

### SUMMARY

The embodiments of the disclosure provide a display substrate and a display device. When a top sub-pad of a conductive pad of the display substrate is oxidized or even falls off, a larger area of a second sub-pad can be exposed through a second via, and a flexible printed circuit board can be bent at the second via and overlapped with the second sub-pad through the second via, so that the problem of poor contact between the flexible printed circuit board and the second sub-pad because the second via is too small can be avoided, and the display substrate can have a better and more stable display effect.

At least one embodiment of the disclosure provides a display substrate, which comprises a base substrate, comprising a display region and a peripheral region at least partially surrounding the display region; and a plurality of conductive pads, in a bonding region, in which the bonding region is in the peripheral region, the plurality of conductive pads are arranged along a first direction, and each of the plurality of conductive pads extends along a second direction intersecting the first direction, and comprises: a first sub-pad, on the base substrate; a first insulating layer, on a side of the first sub-pad away from the base substrate; a second sub-pad, on a side of the first insulating layer away from the first sub-pad; a second insulating layer, on a side of the second sub-pad away from the first insulating layer; a first via, penetrating the first insulating layer, and the second sub-pad being directly connected with the first sub-pad through the first via; and a second via, penetrating the second insulating layer to expose a part of the second sub-pad, in which at least one first via is provided between the first sub-pad and a corresponding second sub-pad, an orthographic projection of the first via on the base substrate overlaps with an orthographic projection of at least one second via on the base substrate, and at least one second via has a size in the second direction being larger than a size in the first direction.

For example, in the display substrate provided by an embodiment of the disclosure, a ratio of the size of the second via in the second direction to the size of the second via in the first direction is greater than or equal to 5.

For example, in the display substrate provided by an embodiment of the disclosure, a ratio of an area of the orthographic projection of the at least one second via on the base substrate to an area of an orthographic projection of the second sub-pad on the base substrate is greater than or equal to 0.5.

For example, in the display substrate provided by an embodiment of the disclosure, a ratio of the size of the at least one second via in the first direction to a size of the second sub-pad in the first direction is greater than or equal to 0.5.

For example, in the display substrate provided by an embodiment of the disclosure, a ratio of the size of the at least one second via in the second direction to a size of the second sub-pad in the second direction is greater than or equal to 0.7.

For example, in the display substrate provided by an embodiment of the disclosure, an orthographic projection of the second via on the base substrate covers the orthographic projection of the first via on the base substrate.

For example, in the display substrate provided by an embodiment of the disclosure, each of the plurality of conductive pads further comprises: a third sub-pad, on a side of the second insulating layer away from the second sub-pad, in which the third sub-pad is directly connected with the second sub-pad through the second via.

For example, in the display substrate provided by an embodiment of the disclosure, the third sub-pad comprises: a first sub-layer, at least partially located in the second via and directly connected with the second sub-pad; and an oxide, at a periphery of the second via, in the second via, or on a side of the first sub-layer away from the second sub-pad, in which a material of the first sub-layer comprises a transparent conductive oxide.

For example, in the display substrate provided by an embodiment of the disclosure, the first sub-layer comprises at least one opening, and an orthographic projection of the opening on the base substrate falls within an orthographic projection of the second via on the base substrate.

For example, in the display substrate provided by an embodiment of the disclosure, the third sub-pad further comprises: a second sub-layer, on a side of the first sub-layer away from the second sub-pad, in which a material of the second sub-layer comprises a conductive metal, and the oxide comprises an oxide of the conductive metal.

For example, in the display substrate provided by an embodiment of the disclosure, the third sub-pad further comprises a third sub-layer, at least partially located on a side of the second sub-layer away from the second sub-pad, a material of the third sub-layer comprises a transparent conductive oxide.

For example, in the display substrate provided by an embodiment of the disclosure, each of the plurality of conductive pads further comprises: a fourth sub-pad, on a side of the third sub-pad away from the second insulating layer, in which a material of the fourth sub-pad comprises a transparent conductive oxide.

For example, in the display substrate provided by an embodiment of the disclosure, a size of the first via in the second direction is larger than a size of the first via in the first direction.

For example, in the display substrate provided by an embodiment of the disclosure, a ratio of the size of the first via in the second direction to the size of the first via in the first direction is greater than or equal to 5.

For example, in the display substrate provided by an embodiment of the disclosure, a ratio of an area of an orthographic projection of at least one first via on the base substrate to an area of an orthographic projection of the first sub-pad on the base substrate is greater than or equal to 0.5.

For example, in the display substrate provided by an embodiment of the disclosure, a ratio of a size of at least one first via in the first direction to a size of the first sub-pad in the first direction is greater than or equal to 0.5.

For example, in the display substrate provided by an embodiment of the disclosure, a ratio of a size of at least one first via in the second direction to a size of the first sub-pad in the second direction is greater than or equal to 0.7.

For example, in the display substrate provided by an embodiment of the disclosure, a ratio of a size of the first via in the second direction to a size of the first via in the first direction is less than or equal to 2.

For example, in the display substrate provided by an embodiment of the disclosure, the second insulating layer comprises only one second via, and a ratio of a size of the second via in the second direction to a size of the second sub-pad in the second direction is greater than or equal to 0.7, the first insulating layer comprises only one first via, and a ratio of a size of the first via in the second direction to a size of the first sub-pad in the second direction is greater than or equal to 0.7.

For example, in the display substrate provided by an embodiment of the disclosure, the second insulating layer comprises only one second via, and a ratio of a size of the second via in the second direction to a size of the second sub-pad in the second direction is greater than or equal to 0.7, the first insulating layer comprises a plurality of first vias.

For example, the display substrate provided by an embodiment of the disclosure further comprises: a plurality of pixel units, in the display region, in which each of the plurality of pixel units comprises a pixel driving circuit and a light emitting element, the pixel driving circuit is on the base substrate, and the light emitting element is on a side of the pixel driving circuit away from the base substrate, and the pixel driving circuit is configured to drive the light emitting element to emit light, the pixel driving circuit comprises a transistor, the transistor comprises a first electrode, a second electrode and a gate electrode, the gate electrode and the first sub-pad are in a same conductive layer, and the first electrode and the second electrode are in a same conductive layer; the light emitting element comprises a first electrode and a second electrode, the third sub-pad and the first electrode of the light emitting element are in a same conductive layer, and the second electrode of the light emitting element is on a side of the first electrode of the light emitting element away from the base substrate.

At least one embodiment of the disclosure provides a display device, which comprises the display substrate provided by any one of the above embodiments.

### BRIEF DESCRIPTION OF DRAWINGS

In order to more clearly illustrate technical solutions of the embodiments of the present disclosure, the attached drawings of the embodiments will be briefly introduced below. Obviously, the attached drawings in the following description only relate to some embodiments of the present disclosure, and are not limited to the present disclosure.

FIG. 1 is a schematic structural view of a conductive pad of a display substrate;

FIG. 2 is a schematic cross-sectional view of the conductive pad shown in FIG. 1 along a second direction;

FIG. 3 is an electron microscope view of a part of the structure of the conductive pad shown in FIG. 1;

FIG. 4 is a microscope view of the conductive pad shown in FIG. 1;

FIG. 5 is a schematic diagram of a lighting screen of the display substrate corresponding to the conductive pad shown in FIG. 4;

FIG. 6 is a schematic structural view of a display substrate provided by an embodiment of the present disclosure;

FIG. 7 is a partially enlarged schematic view of a conductive pad provided by an embodiment of the present disclosure;

FIG. 8 is a schematic cross-sectional view of the conductive pad shown in FIG. 7 along a second direction;

FIG. 9 is another schematic cross-sectional view of the conductive pad shown in FIG. 7 along the second direction;

FIG. 10 is a partially enlarged schematic view of another conductive pad provided by an embodiment of the present disclosure;

FIG. 11 is a schematic cross-sectional view of the conductive pad shown in FIG. 10 along a second direction;

FIG. 12 is a partially enlarged schematic view of another conductive pad provided by an embodiment of the present disclosure;

FIG. 13 is a schematic cross-sectional view of the conductive pad shown in FIG. 12 along a second direction;

FIG. 14 is another schematic cross-sectional view of the conductive pad shown in FIG. 12 along a second direction;

FIG. 15 is another schematic cross-sectional view of the conductive pad shown in FIG. 12 along a second direction;

FIG. 16 is another schematic cross-sectional view of the conductive pad 200 shown in FIG. 10 along a second direction Y;

FIG. 17 is a partially enlarged schematic view of another conductive pad provided by an embodiment of the present disclosure;

FIG. 18 is a schematic cross-sectional view of the conductive pad shown in FIG. 17 along a second direction;

FIG. 19 is a partially enlarged schematic view of another conductive pad provided by an embodiment of the present disclosure;

FIG. 20 is a schematic cross-sectional view of the conductive pad shown in FIG. 19 along a second direction;

FIG. 21 is a schematic cross-sectional view of a display substrate provided by an embodiment of the present disclosure;

FIG. 22 is a partially enlarged schematic view of a bonding region provided by an embodiment of the present disclosure;

FIG. 23 is a schematic cross-sectional view of a conductive pad connected to a flexible printed circuit board according to an embodiment of the present disclosure;

FIG. 24 is a partially enlarged schematic view of another conductive pad provided by an embodiment of the present disclosure;

FIG. 25 is a schematic cross-sectional view of the conductive pad shown in FIG. 24 along a second direction; and

FIG. 26 is a schematic diagram of a display device provided by an embodiment of the present disclosure.

### DETAILED DESCRIPTION

In order to make objectives, technical details, and advantages of the embodiments of the present disclosure clearer, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first”, “second”, etc., which are used in the present disclosure, are not intended to indicate any sequence, amount or importance, but distinguish various components. Also, the terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly.

Unless otherwise defined, the features such as “parallel”, “vertical” and “identical/same” used in the embodiments of the present disclosure all include cases such as “parallel”, “vertical” and “identical/same” in a strict sense, and cases such as “substantially parallel”, “substantially vertical” and “substantially identical/same” contain certain errors. For example, the above-mentioned “substantially” can mean that the difference of the compared objects is within 10% or 5% of the average value of the compared objects. When the number of one component or element is not specified in the following of the disclosed embodiments, it means that the component or element can be one or more, or can be understood as at least one. “At least one” means one or more, and “a plurality of” means at least two. In the embodiments of the present disclosure, “arranged in the same layer” or “located in the same conductive layer” refers to the relationship between a plurality of film layers formed by the same material after the same step (for example, one patterning process). Here, “same layer” or “same conductive layer” does not always mean that the thicknesses of the plurality of film layers are the same or the heights of the plurality of film layers are the same in cross section.

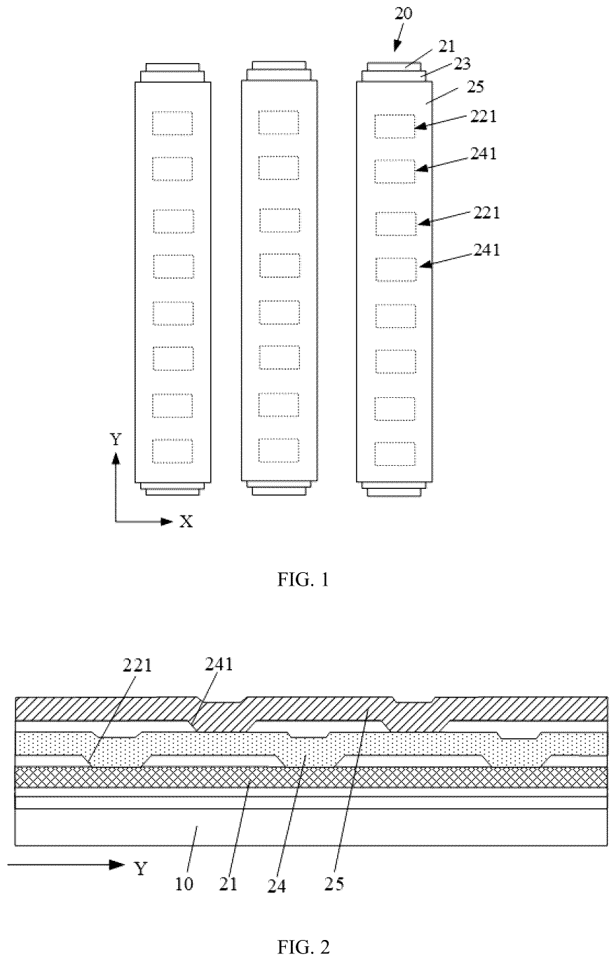

FIG. 1 is a schematic structural view of a conductive pad of a display substrate; FIG. 2 is a schematic cross-sectional view of the conductive pad shown in FIG. 1 along a second direction. As illustrated by FIG. 1, the conductive pads 20 of the OLED display substrate are arranged along a first direction X and each extend along a second direction Y intersecting with the first direction X. The conductive pad 20 includes a bottom sub-pad 21, a middle sub-pad 23 and a top sub-pad 25, and the bottom sub-pad 21 and the middle sub-pad 23 are directly connected through a via 221, and the middle sub-pad 23 and the top sub-pad 25 are directly connected through a via 241. Generally, a size of the via 221 in the second direction Y is smaller than a size of the via 221 in the first direction X, and a size of the via 241 in the second direction Y is smaller than a size of the via 241 in the first direction X, and an orthographic projection of the via 221 on the base substrate 10 is staggered with an orthographic projection of the via 241 on the base substrate, that is, the vias 221 and the vias 241 are staggered in the second direction Y.

In order to reduce the manufacturing process, any sub-pad of the conductive pad can be in the same layer as a conductive layer of a pixel driving circuit in the display region, for example, the bottom sub-pad 21 is located in the same layer as a gate layer, the middle sub-pad 23 is located in the same layer as a source-drain conductive layer, and the top sub-pad 25 is located in the same layer as an anode layer.

The OLED display substrate may include a top emission type and a bottom emission type according to the light emitting mode. For the bottom emission type, the anode layer is usually made of indium tin oxide (ITO), so the top sub-pad 25 of the conductive pad can protect the middle sub-pad and the bottom sub-pad from oxidation. However, for the top emission type, the material of the anode layer is usually a stacked structure of bottom ITO, silver and top ITO, and the top ITO of the anode layer needs to be matched with the optical design of OLED, and the thickness of the top ITO is relatively thin. When the top sub-pad 25 is arranged in the same layer as the anode layer, the silver of the top sub-pad 25 is easy to be oxidized, and the top sub-pad 25 will fall off in serious regions, resulting in abnormal lapping connection of the conductive pad.

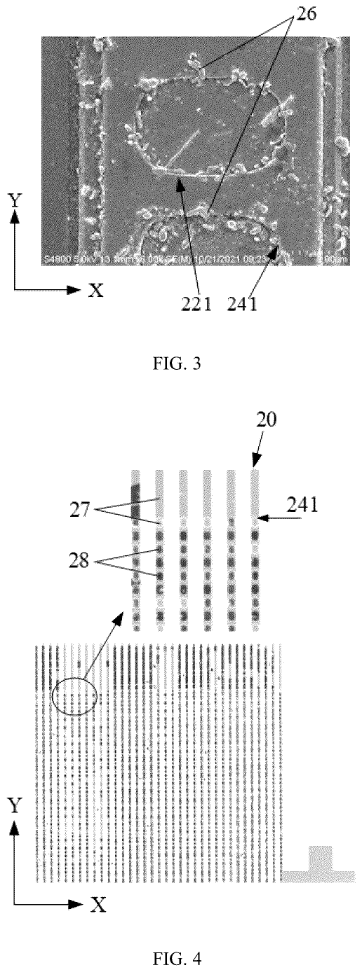

FIG. 3 is an electron microscope view of a part of the structure of the conductive pad shown in FIG. 1. As illustrated by FIG. 3, silver oxide particles 26 are formed in some regions of the conductive pad 20, and the silver oxide particles 26 are partially gathered around the vias and in the vias. FIG. 4 is a microscope view of the conductive pad shown in FIG. 1. As illustrated by FIG. 4, when the oxidation of the silver of the top sub-pad 25 is serious, some regions of the top sub-pad 25 will fall off, and the conductive metal in the region 27, namely the light-colored region, has fallen off, and some silver remains in the region 28, namely the dark-colored region. As can be seen from FIG. 4, much of the silver that has not fallen off remains in the via 241. However, the size of the via 241 is relatively small, which not only makes the silver in the via 241 less, but also makes it difficult for the flexible printed circuit board to overlap with the silver in the via 241, especially there are silver oxide particles around the via 241 and in the via 241, resulting in poor lapping connection. Moreover, the top sub-pads 25 in some vias 241 all fall off, so the relatively small vias 241 make it difficult for the flexible printed circuit board to overlap with the middle sub-pads 23 exposed by the vias 241, and it is easy to generate some undesirable phenomena such as virtual connection, thus affecting the display of the display substrate.

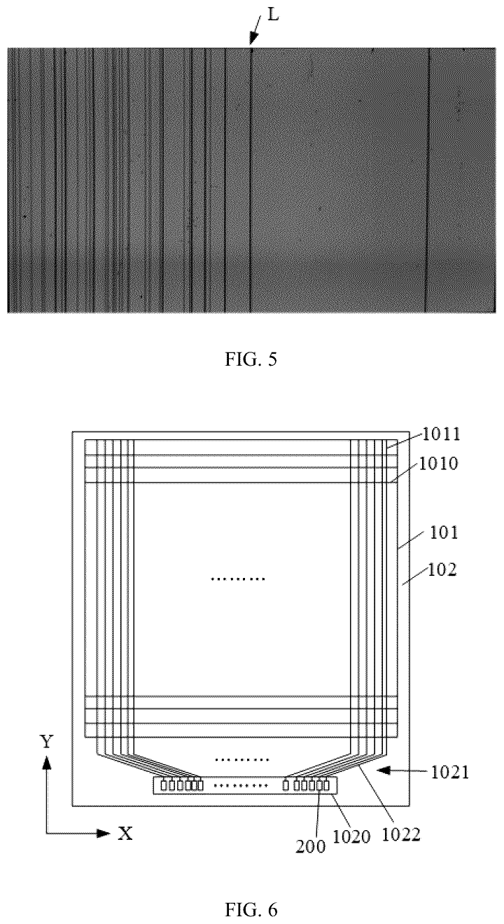

FIG. 5 is a schematic diagram of a lighting screen of the display substrate corresponding to the conductive pad shown in FIG. 4. As illustrated by FIG. 5, after the display substrate is lit, a large number of vertical dark lines L will appear on the display substrate, thus affecting the normal display of the display substrate.

In this regard, embodiments of the present disclosure provide a display substrate and a display device. The display substrate includes a base substrate including a display region and a peripheral region at least partially surrounding the display region. A plurality of conductive pads are located in a bonding region, and the bonding region is located in the peripheral region. The plurality of conductive pads are arranged along a first direction, and each of the plurality of conductive pads extends along a second direction intersecting with the first direction. Each of the plurality of conductive pads includes a first sub-pad, a first insulating layer, a second sub-pad, a second insulating layer, a first via and a second via. The first sub-pad is located on the base substrate, the first insulating layer is located on a side of the first sub-pad away from the base substrate, the second sub-pad is located on a side of the first insulating layer away from the first sub-pad, the first via penetrates the first insulating layer, the second sub-pad is directly connected with the first sub-pad through the first via, and the second via penetrates the second insulating layer to expose a part of the second sub-pad. At least one first via is provided between the first sub-pad and a corresponding second sub-pad, and an orthographic projection of the first via on the base substrate overlaps with an orthographic projection of at least one second via on the base substrate, and at least one second via has a size in the second direction being larger than a size (of the at least one second via) in the first direction. For example, a ratio of the size of the second via in the second direction to the size of the second via in the first direction is greater than or equal to 5.

In the display substrate provided by the embodiments of the present disclosure, the first sub-pad and the second sub-pad of each of the plurality of conductive pads of the display substrate are conductive pads, the first insulating layer is arranged between the first sub-pad and the second sub-pad, the first sub-pad and the second sub-pad are directly connected through the first via in the first insulating layer, at least one second via is arranged in the second insulating layer, and the second via exposes a part of the second sub-pad, the size of the second via in the second direction is larger than the size of the second via in the first direction, and the orthographic projection of the second via on the base substrate overlaps with the orthographic projection of the first via on the base substrate, so that not only each second via can expose a larger area of the second sub-pad, but also each of the plurality of conductive pads can expose a larger area of second sub-pad through at least one second via. Therefore, even if the top sub-pad falls off, because each second via can expose a larger area of the second sub-pad, and the second via itself has a relatively large size in the second direction, a flexible printed circuit board can be bent at the second via and overlap with the second sub-pad through the second via, thus avoiding the problem that the flexible printed circuit board cannot contact with the second sub-pad because the second via is too small. Therefore, the display substrate greatly reduces the phenomenon of poor lapping connection or no lapping connection. Therefore, the flexible printed circuit board can be better and more easily overlapped with the conductive pad, and the connection with the display substrate can be better realized through the conductive pad, so that the display substrate can have a better and more stable display effect.

Hereinafter, the display substrate and the display device provided by the embodiments of the present disclosure will be described in detail with reference to the drawings.

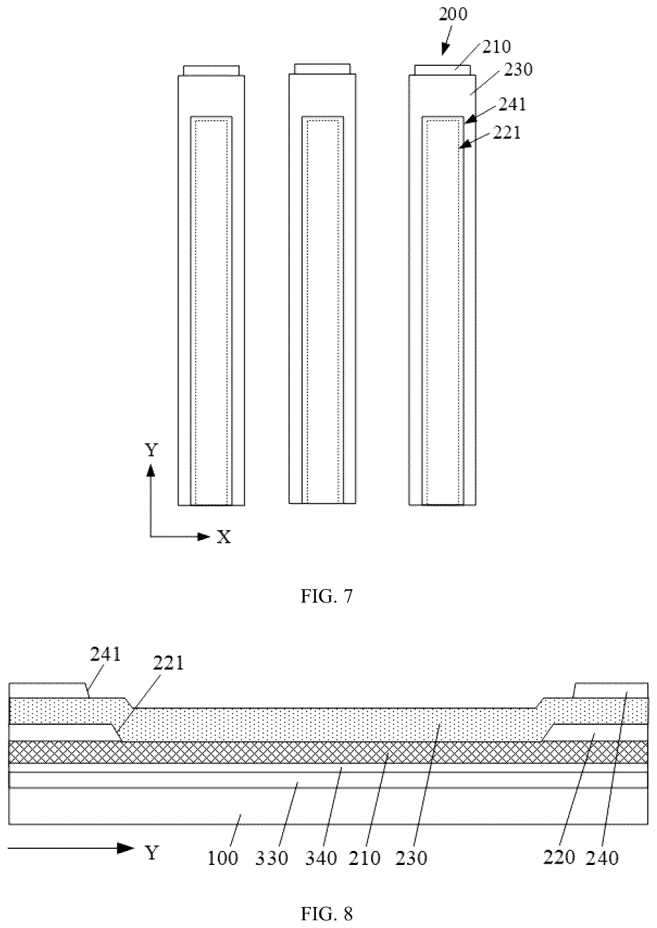

An embodiment of the present disclosure provides a display substrate. FIG. 6 is a schematic structural view of a display substrate provided by an embodiment of the present disclosure, FIG. 7 is a partially enlarged schematic view of a conductive pad provided by an embodiment of the present disclosure, and FIG. 8 is a schematic cross-sectional view of the conductive pad shown in FIG. 7 along a second direction.

As illustrated by FIG. 6, the display substrate includes a base substrate including a display region 101 and a peripheral region 102 at least partially surrounding the display region 101. The display region 101 includes pixel units and scanning lines, data lines and power lines that provide control signals, data signals and voltage signals for the pixel units. For example, as illustrated by FIG. 6, the display region 101 includes a plurality of gate lines 1010 extending in one direction and data lines 1011 extending in another direction intersecting with the direction in which the gate lines extend. The peripheral region 102 of the display substrate includes a fan-out region 1021 and a bonding region 1020. The fan-out region 1021 is closer to the display region 101 than the bonding region 1020. The fan-out region 1021 includes a plurality of leads 1022, and the bonding region 1020 includes a plurality of conductive pads 200. The leads 1022 correspond to the conductive pads 200 one by one, and one end of the lead 1022 is connected to the data line 1011, the other end of the lead 1022 is connected with the conductive pad 200, and the conductive pad 200 is connected with a flexible printed circuit board, for example, with a corresponding conductive pad or bonding pad on the flexible printed circuit board, so that the driving circuit board can provide driving signals for the display substrate. For example, the lead 1022 may be located in the same conductive layer as the data line 1011 in the display region 101 or in a different conductive layer from the data line 1011 in the display region 101. When the lead 1022 and the data line 1011 are located in different conductive layers, the lead 1022 and the data line 1011 may be directly connected through the via in the insulating layer between them.

As illustrated by FIGS. 6 to 8, the plurality of conductive pads 200 of the bonding region 1020 are arranged along a first direction X, and each of the plurality of conductive pads 200 extends along a second direction Y intersecting with the first direction X. Each of the plurality of conductive pads 200 includes a first sub-pad 210, a first insulating layer 220, a second sub-pad 230, a second insulating layer 240, a first via 221 and a second via 241. The first sub-pad 210 is located on the base substrate 100, the first insulating layer 220 is located on a side of the first sub-pad 210 away from the base substrate 100, the second sub-pad 230 is located on a side of the first insulating layer 220 away from the first sub-pad 210, the second insulating layer 240 is located on a side of the second sub-pad 230 away from the first insulating layer 220, the first via 221 penetrates the first insulating layer 220, and the second sub-pad 230 is directly connected with the first sub-pad 210 through the first via 221, the second via 241 penetrates the second insulating layer 240, so as to expose a part of the second sub-pad 230. At least one first via 221 is provided between the first sub-pad 210 and a corresponding second sub-pad 230, an orthographic projection of the first via 221 on the base substrate 100 overlaps with an orthographic projection of at least one second via 241 on the base substrate 100. At least one second via 241 has a size in the second direction Y being larger than a size in the first direction X, for example, a ratio of the size of the second via 241 in the second direction Y to the size of the second via 241 in the first direction X is larger than or equal to 5.

In the display substrate provided by the embodiments of the present disclosure, the first sub-pad 210 and the second sub-pad 230 of each of the plurality of conductive pads 200 are both conductive pads 200, the first insulating layer 220 is arranged between the first sub-pad 210 and the second sub-pad 230, the first sub-pad 210 and the second sub-pad 230 are directly connected through the first via 221 in the first insulating layer 220, and at least one second via 241 is provided in the second insulating layer 240. The second via 241 exposes a part of the second sub-pad 230, and the size of the second via 241 in the second direction Y is larger than the size of the second via 241 in the first direction X. The orthographic projection of the second via 241 on the base substrate 100 overlaps with the orthographic projection of the first via 221 on the base substrate 100, so that not only each second via 241 can expose a larger area of the second sub-pad 230, but also each of the plurality of conductive pads 200 can expose a larger area of the second sub-pad 230 through at least one second via 241. Therefore, even if the top sub-pad falls off, the top sub-pad is located on a side of the second sub-pad 230 away from the base substrate, because each second via 241 can expose a larger area of the second sub-pad 230 and the second via 241 itself has a relatively large size in the second direction Y, the flexible printed circuit board can be bent at the second via 241 and overlap with the second sub-pad 230 through the second via 241, so that the problem that the flexible circuit board cannot contact the second sub-pad 230 because the second via 241 is too small can be avoided. Therefore, the display substrate greatly reduces the phenomenon of poor lapping connection or no lapping connection. Therefore, the flexible printed circuit board can be better and easily overlapped with the conductive pad 200, and be better connected with the display substrate through the conductive pad 200, so that the display substrate can have a better and more stable display effect.

It should be noted that, in order to clearly show the first sub-pad 210 and the second sub-pad 230 of each of the plurality of conductive pads 200 and their stacked relationship, the first insulating layer 220 and the second insulating layer 240 are omitted in FIG. 7, and the sizes of the first sub-pad 210 and the second sub-pad 230 of each of the plurality of conductive pads 200 in the second direction Y are only partially shown. It is also schematic that the size of the second sub-pad 230 of each of the plurality of conductive pads 200 in the first direction X is larger than the size of the first sub-pad 210 in the first direction X, and the size of the second sub-pad 230 of each of the plurality of conductive pads 200 in the first direction X may be smaller than or equal to the size of the first sub-pad 210 in the first direction X, which is not limited by the embodiments of the present disclosure. For example, a side of the first sub-pad 210 close to the base substrate 100 may also be provided with a buffer layer 330 and an insulating layer 340, for example, the insulating layer 340 may be a first gate insulating layer.

In some examples, as illustrated by FIG. 7 and FIG. 8, the size of the second via 241 in the second direction Y is larger than the size of the second via 241 in the first direction X. For example, a ratio of the size of the second via 241 in the second direction Y to the size of the second via 241 in the first direction X may be any numerical value greater than or equal to 5, for example, the ratio of the size of the second via 241 in the second direction Y to the size of the second via 241 in the first direction X may be larger than or equal to 10, for example, be larger than or equal to 18, for example, be larger than or equal to 25. According to the size designs of different conductive pads 200, the ratio of the size of the second via 241 in the second direction Y to the size of the second via 241 in the first direction X can be designed to have different values.

In some examples, as illustrated by FIG. 7 and FIG. 8, a ratio of an area of an orthographic projection of at least one second via 241 in the second insulating layer 240 of each of the plurality of conductive pads 200 on the base substrate 100 to an area of an orthographic projection of the second sub-pad 230 of the conductive pad 200 on the base substrate 100 is greater than or equal to 0.5. Therefore, the larger the ratio of the area of the orthographic projection of at least one second via 241 in the second insulating layer 240 on the base substrate 100 to the area of the orthographic projection of the second sub-pad 230 of the conductive pad 200 on the base substrate 100, the larger the opening of the second via 241 and the larger the exposed area of the second sub-pad 230.

For example, in the case where the second insulating layer 240 of each of the plurality of conductive pads 200 includes one second via 241, the ratio of the area of the orthographic projection of the second via 241 on the base substrate 100 to the area of the orthographic projection of the second sub-pad 230 of the conductive pad 200 on the base substrate 100 is greater than or equal to 0.5. For example, in the case where the second insulating layer of each of the plurality of conductive pads 200 includes a plurality of second vias 241, the ratio of the total area of the orthographic projections of the second vias 241 on the base substrate 100 to the area of the orthographic projection of the second sub-pad 230 of the conductive pad 200 on the base substrate 100 is greater than or equal to 0.5. For example, the ratio of the areas may be greater than or equal to 0.8. For example, the ratio of the areas may be 0.5, 0.55, 0.6, 0.65, 0.7, 0.75, 0.8, 0.85, 0.9, 0.95, 0.98, 0.99, etc., which are not listed here. According to the size design of different conductive pads 200, the ratio of the area of the orthographic projection of the at least one second via 241 in the second insulating layer 240 on the base substrate 100 to the area of the orthographic projection of the second sub-pad 230 on the base substrate 100 can be designed to have different values.

In some examples, as illustrated by FIG. 7 and FIG. 8, a ratio of the size of at least one second via 241 in the first direction X to the size of the second sub-pad 230 in the first direction X is greater than or equal to 0.5. Therefore, the larger the ratio of the size of the second via 241 in the first direction X to the size of the second sub-pad 230 in the first direction X, the larger the size of the opening of each second via 241 and the larger the exposed area of the second sub-pad 230.

For example, the ratio of the size of the second via 241 in the first direction X to the size of the second sub-pad 230 in the first direction X may be 0.5, 0.65, 0.7, 0.75, 0.8, 0.85, 0.9, 0.95, 0.98, 1, etc., which are not listed here.

For example, the ratio of the size of the second via 241 in the first direction X to the size of the second sub-pad 230 in the first direction X and the ratio of the size of the second via 241 in the second direction Y to the size of the second via 241 in the first direction X may all be selected as relatively large values. For example, the ratio of the size of the second via 241 in the first direction X to the size of the second sub-pad 230 in the first direction X may be greater than 0.8, and at the same time, the ratio of the size of the second via 241 in the second direction Y to the size of the second via 241 in the first direction X may be greater than 10, so that the larger the size of the opening of the second via 241, the larger the exposed area of the second sub-pad 230.

In some examples, as illustrated by FIG. 7 and FIG. 8, the ratio of the size of at least one second via 241 in the second direction Y to the size of the second sub-pad 230 in the second direction Y is greater than or equal to 0.7. For example, the ratio of sizes may be 0.7, 0.75, 0.8, 0.85, 0.9, 0.95, 0.98, 0.99, 1, etc., which are not listed here. Therefore, the closer the ratio of the size of the second via 241 in the second direction Y to the size of the second sub-pad 230 in the second direction Y is to 1, the larger the size of the opening of the second via 241 and the larger the exposed area of the second sub-pad 230.

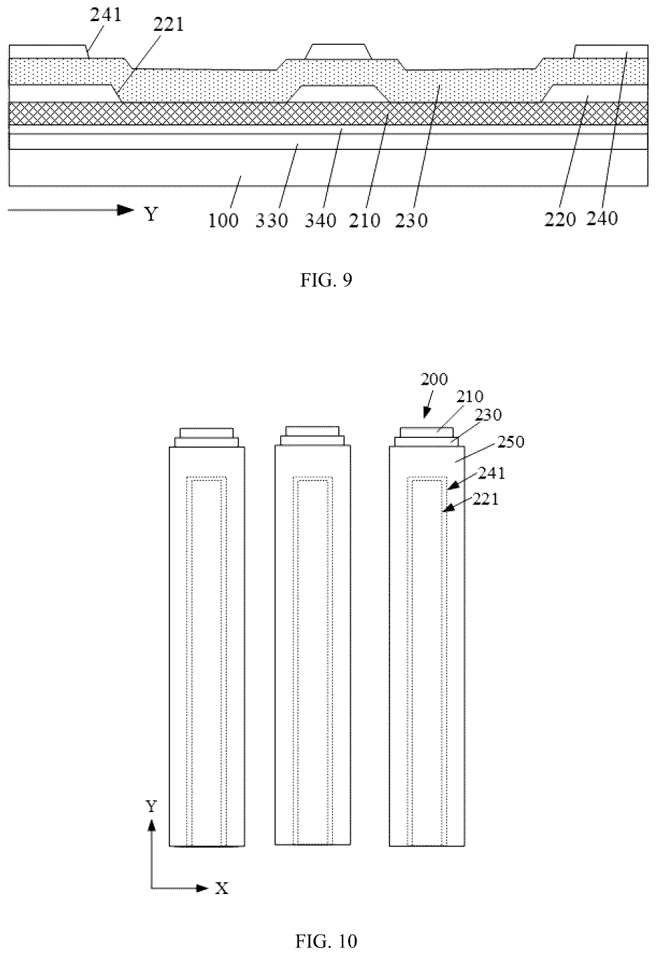

In some examples, as illustrated by FIG. 7 and FIG. 8, the second insulating layer 240 includes only one second via 241, so that the size of the only one second via 241 in the second insulating layer 240 in the second direction Y can be maximized, and the area of the second sub-pad 230 exposed by the second via 241 can be maximized, so that when the top sub-pad falls off, the flexible printed circuit board can better overlap with the second sub-pad 230, and the display substrate can have a better and more stable display effect. FIG. 9 is another schematic cross-sectional view of the conductive pad shown in FIG. 7 along the second direction. As illustrated by FIG. 7 and FIG. 9, the second insulating layer 240 includes at least two second vias 241. The first insulating layer 220 includes at least two first vias 221. Of course, the number of the first vias 221 and the number of the second vias 241 are not limited in the embodiments of the present disclosure, and the number of the first vias 221 and the number of the second vias 241 can be designed according to the sizes of different conductive pads 200.

In some examples, as illustrated by FIG. 7 and FIG. 9, the orthographic projection of the first via 221 on the base substrate 100 overlaps with the orthographic projection of the second via 241 on the base substrate 100. The figures schematically show that the orthographic projection of the first via 221 on the base substrate 100 falls within the orthographic projection of the second via 241 on the base substrate 100. Of course, the embodiments of the present disclosure are not limited thereto. For example, the orthographic projection of the first via 221 on the base substrate 100 may coincide with the orthographic projection of the second via 241 on the base substrate 100. In this case, the sizes of the first via 221 in the first direction X and the second direction Y are the same as the sizes of the second via 241 in the first direction X and the second direction Y, respectively. For example, the orthographic projection of the first via 221 on the base substrate 100 may also partially fall within the orthographic projection of the second via 241 on the base substrate 100 and partially fall outside the orthographic projection of the second via 241 on the base substrate 100.

For example, the first sub-pad 210 and the second sub-pad 230 may be made of metal materials such as copper, aluminum and titanium. For example, the first sub-pad 210 and the second sub-pad 230 may be formed in single-layer structures or multi-layer structures. For example, the first insulating layer 220 and the second insulating layer 240 may use inorganic insulating materials such as silicon oxide, silicon nitride or silicon oxynitride, or may include organic insulating materials such as polyimide, polyimide, poly-phthalamide, acrylic resin, benzocyclobutene or phenolic resin. Of course, the materials of the first sub-pad 210, the first insulating layer 220, the second sub-pad 230 and the second insulating layer 240 are not limited in the embodiments of the present disclosure.

For example, the base substrate 100 may be a glass substrate, a quartz substrate, a metal substrate or a resin substrate. For example, the material of the base substrate 100 may include an organic material, such as polyimide, polycarbonate, polyacrylate, polyetherimide, polyethersulfone, polyethylene terephthalate and polyethylene naphthalate, and the base substrate 100 may be a flexible substrate or a non-flexible substrate, which is not limited by the embodiments of the present disclosure.

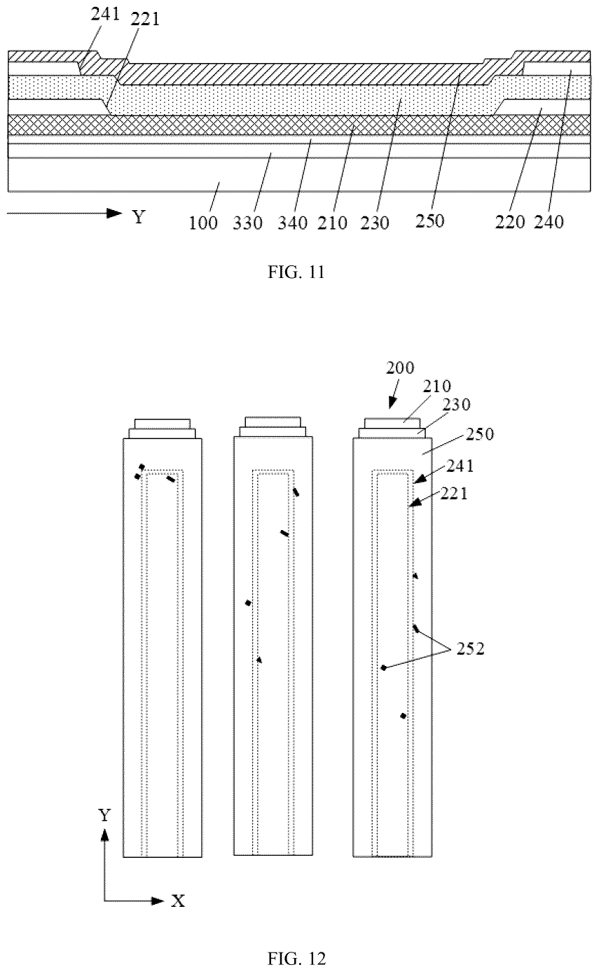

FIG. 10 is a partially enlarged schematic view of another conductive pad provided by an embodiment of the present disclosure; FIG. 11 is a schematic cross-sectional view of the conductive pad shown in FIG. 10 along a second direction. As illustrated by FIG. 10 and FIG. 11, each of the plurality of conductive pads 200 further includes a third sub-pad 250, and the third sub-pad 250 is located on a side of the second insulating layer 240 away from the second sub-pad 230, and is directly connected with the second sub-pad 230 through the second via 241. The third sub-pad 250 of each of the plurality of conductive pads 200 is a conductive pad 200, and a second insulating layer 240 is arranged between the third sub-pad 250 and the second sub-pad 230, and the third sub-pad 250 is directly connected with the second sub-pad 230 through a second via 241 in the second insulating layer 240. By arranging the third sub-pad 250, the flexible printed circuit board can directly overlap with the third sub-pad 250, and flexible printed circuit board can better overlap with the conductive pad 200. In addition, by arranging the third sub-pad 250, the flexible printed circuit board can be connected with the display substrate through the multi-layer conductive pad 200, and the conductive performance of the conductive pad 200 can also be improved.

For example, the material of the third sub-pad 250 may include transparent conductive oxide. For example, the third sub-pad 250 may have a stacked structure, and the material of the top layer of the stacked structure includes transparent conductive oxide. Therefore, the third sub-pad 250 can also protect the first sub-pad 210 and the second sub-pad 230 from oxidation, and the first sub-pad 210 and the second sub-pad 230 can be made of conductive metal with better conductivity, and the conductive pad 200 will also have better conductivity. The embodiments of the present disclosure do not limit the structure and material of the third sub-pad 250.

For example, as illustrated by FIG. 10, an orthographic projection of the third sub-pad 250 on the base substrate 100 covers the orthographic projection of the second sub-pad 230 on the base substrate 100. The embodiments of the present disclosure are not limited thereto, for example, the orthographic projection of the third sub-pad on the base substrate may also be located within the orthographic projection of the second sub-pad on the base substrate.

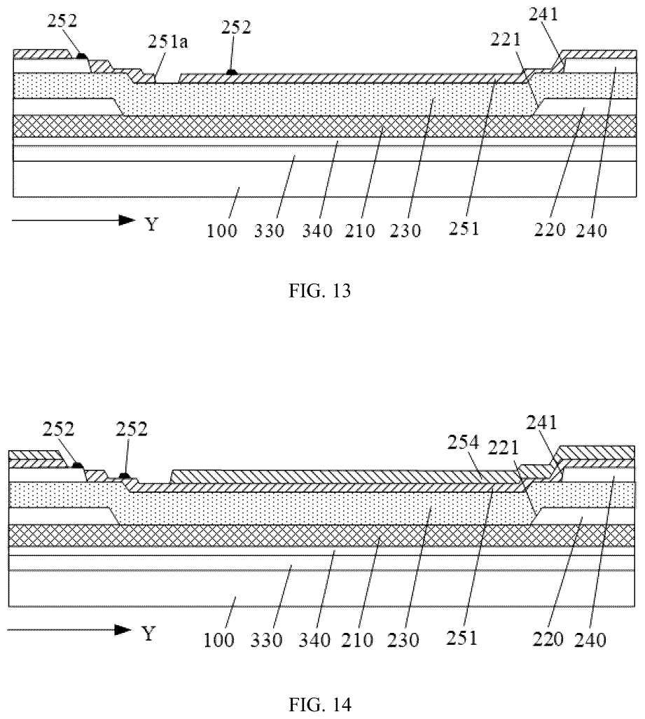

FIG. 12 is a partially enlarged schematic view of another conductive pad provided by an embodiment of the present disclosure; FIG. 13 is a schematic cross-sectional view of the conductive pad shown in FIG. 12 along a second direction. As illustrated by FIG. 12 and FIG. 13, the third sub-pad 250 includes a first sub-layer 251 and an oxide 252. The first sub-layer 251 is at least partially located in the second via 241 and directly connected with the second sub-pad 230. The oxide 252 is located at the periphery of the second via 241, and the material of the first sub-layer 251 includes transparent conductive oxide. Therefore, in the case where a side of the first sub-layer 250 away from the base substrate 100 is provided with a conductive material layer, the conductive material layer is prone to oxidation to form oxide 252 or even falls off because of oxidation, and the flexible printed circuit board can overlap with the first sub-layer 251 through the second via 241 with larger size and larger area, so that the influence of the oxide 252 or the fall-off on the lapping connection between the flexible printed circuit board and the conductive pad 200 can be reduced. In addition, the material of the first sub-layer 251 includes transparent conductive oxide, which can also protect the first conductive pad 200 and the second conductive pad 200 from oxidation. The first conductive pad 200 and the second conductive pad 200 can use conductive metal with better conductivity, so that the conductive pad 200 can have better conductivity.

In some examples, as illustrated by FIG. 12 and FIG. 13, the third sub-pad 250 further includes an oxide 252 located within the second via 241. The oxide 252 is also located on a side of the first sub-layer 251 away from the second sub-pad 230. For example, in the case where the conductive material of the third sub-pad 250 is oxidized to form the oxide 252, the flexible printed circuit board can overlap with the first sub-layer 251 through the second via 241 with larger size and larger area, so that the influence of the oxide 252 on the lapping connection between the flexible printed circuit board and the conductive pad 200 can be reduced, and the influence on the input signal can be reduced.

For example, in the case where the side of the first sub-layer 250 away from the base substrate 100 further includes a conductive material layer, the conductive material layer is prone to oxidation to form the oxide 252 or the conductive material layer is oxidized to fall off. The oxide 252 will affect the lapping connection between the third sub-pad 250 and flexible printed circuit board, and the fall-off of conductive material will also affect the lapping connection between the third sub-pad 250 and flexible printed circuit board, so that the third sub-pad 250 cannot facilitate the connection between the flexible printed circuit board and the display substrate, thus affecting the display effect of the display substrate. Therefore, the larger the size of the second via 241, the flexible printed circuit board can be bent at the second via 241 and overlap with the first sub-layer 251, so that the influence of the oxide 252 or the fall-off of the conductive material layer on the lapping connection between the flexible printed circuit board and the conductive pad 200 can be reduced, and the display substrate can have a better and more stable display effect.

In some examples, as illustrated by FIG. 13, the first sub-layer 251 may further include at least one opening 251a, and an orthographic projection of the opening 251a on the base substrate 100 falls within the orthographic projection of the second via 241 on the base substrate 100. In the case where the third sub-pad 250 falls off seriously, the first sub-layer 251 will also fall off partially, so that the first sub-layer 251 will include the opening 251a in the region where the fall-off is serious. Therefore, the larger the size or area of the second via 241 is, the flexible printed circuit board can be bent at the second via 241 and overlap with the first sub-layer 251 through the second via 241 or with the second sub-pad 230 through the opening 251 a, so that the flexible printed circuit board can better and more easily overlap with the conductive pad 200.

In some examples, as illustrated by FIG. 13, at least a part of the first sub-layer 251 may also be located outside the second via 241.

In some examples, in the case where the side of the first sub-layer 250 away from the base substrate 100 is further provided with a conductive material layer, and the conductive material layer is severely oxidized, the third sub-pad 250 may fall off completely, so that the conductive pad 200 only includes the first sub-pad 210 and the second sub-pad 230. Through the size design of the second via 241, the flexible printed circuit board can overlap with the second sub-pad 230 through the second via 241 with a larger size, which greatly reduces the phenomenon of poor lapping connection or no lapping connection between the flexible printed circuit board and the second sub-pad 230, so that even if the third sub-pad 250 falls off, the flexible printed circuit board can be overlapped with the conductive pad better and more easily, so that the display substrate can have a better and more stable display effect.

For example, the material of the first sub-layer 251 includes indium tin oxide. For example, the material of the oxide 252 includes silver oxide. Of course, the materials of the first sub-layer 251 and the oxide 252 are not limited in the embodiments of the present disclosure.

FIG. 14 is another schematic cross-sectional view of the conductive pad shown in FIG. 12 along a second direction. As illustrated by FIG. 14, the third sub-pad 250 further includes a second sub-layer 254, the second sub-layer 254 is located on a side of the first sub-layer 251 away from the second sub-pad 230. The material of the second sub-layer 254 includes a conductive metal, and the oxide 252 includes an oxide of the conductive metal. Therefore, when the oxide 252 is formed after the oxidation reaction of some conductive metals in the second sub-layer 254, the flexible printed circuit board can overlap with the first sub-layer 251 and the unoxidized second sub-layer 254 through the second via 241 with larger size, which can greatly reduce the influence of the oxide 252 on the poor lapping connection or no lapping connection between the flexible printed circuit board and the conductive pad 200.

In some examples, as illustrated by FIG. 14, a part of the second sub-layer 254 may be located in the second via 241, and a part of the second sub-layer 254 may also be located outside the second via 241.

In some examples, as illustrated by FIG. 14, the second via 241 includes the oxide 252 therein, and the oxide 252 includes an oxide of a conductive metal. For example, a part of the conductive metal of the second sub-layer 254 undergoes an oxidation reaction to form the oxide 252. Therefore, the flexible printed circuit board can overlap with the second sub-layer 254 through the second via 241 with a larger size and a larger area, and the second via 241 with a larger overlapping area can reduce the influence of the oxide 252 on the overlapping area between the flexible printed circuit board and the conductive pad 200, thus reducing the influence on the input signal.

For example, the material of the second sub-layer includes silver. For example, the material of the oxide 252 includes silver oxide. Of course, the materials of the second sub-layer and the oxide 252 are not limited by the embodiments of the present disclosure.

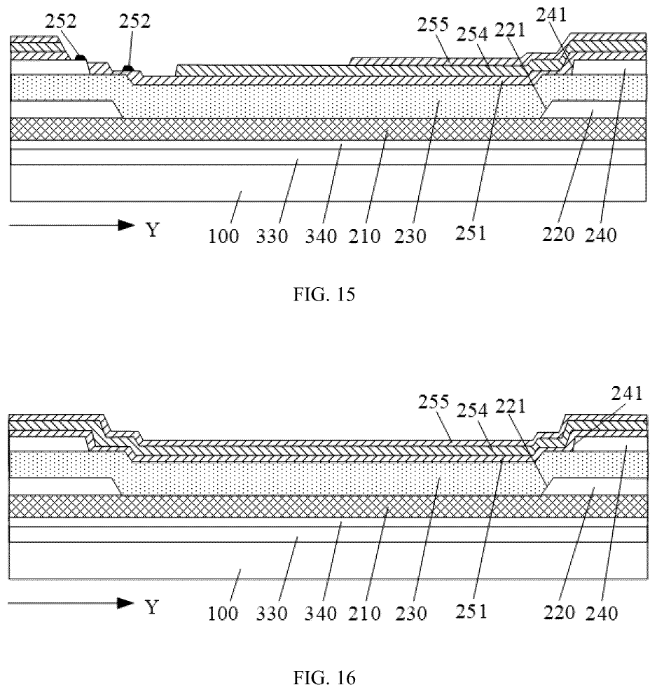

FIG. 15 is another schematic cross-sectional view of the conductive pad shown in FIG. 12 along a second direction. As illustrated by FIG. 15, the third sub-pad 250 further includes a third sub-layer 255, which is at least partially located on a side of the second sub-layer 254 away from the second sub-pad 230. The material of the third sub-layer 255 includes transparent conductive oxide. For example, in the case where the thickness of the third sub-layer 255 is thin, the second sub-layer 254 is prone to partial oxidation or even falls off, so that the flexible printed circuit board can overlap with the second sub-layer 254 through the second via 241 with a larger size and a larger area, which greatly reduces the phenomenon of poor lapping connection or no lapping connection.

For example, the material of the third sub-layer includes indium tin oxide. Of course, the materials of the third sub-layer and the oxide 252 are not limited by the embodiments of the present disclosure.

FIG. 16 is another schematic cross-sectional view of the conductive pad 200 shown in FIG. 10 along a second direction Y. As illustrated by FIG. 16, the third sub-pad 250 includes a first sub-layer 251, a second sub-layer 254 and a third sub-layer 255. The first sub-layer 251 is at least partially located in the second via 241 and directly connected with the second sub-pad 230. The second sub-layer 254 is located on a side of the first sub-layer 251 away from the second sub-pad 230. The third sub-layer 255 is located on a side of the second sub-layer away from the second sub-pad 230. Materials of the first sub-layer 251 and the third sub-layer 255 include transparent conductive oxides, and the material of the second sub-layer 254 includes a conductive metal. The materials of the first sub-layer 251 and the third sub-layer 255 include transparent conductive oxides, which can protect the conductive materials of the second sub-layer 254, the first sub-pad 210 and the second sub-pad 230 from oxidation, and the materials of the second sub-layer 254, the first sub-pad 210 and the second sub-pad 230 may be selected from conductive materials with better conductivity. Moreover, even if the third sub-pad 250 is oxidized or falls off in a partial region, the flexible printed circuit board can overlap with the second sub-layer 254 through the second via 241 with a larger size and a larger area, which greatly reduces the phenomenon of poor lapping connection or no lapping connection.

For example, the transparent conductive oxides of the first sub-layer 251 and the second sub-layer 254 include indium tin oxides, and the conductive metal of the third sub-layer 255 includes silver. Of course, the embodiments of the present disclosure are not limited thereto.

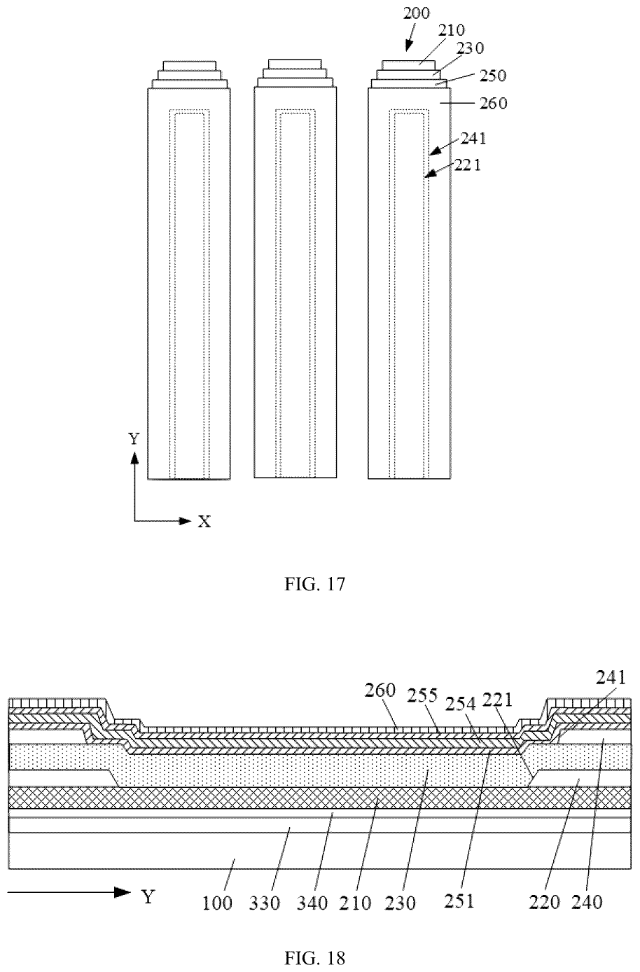

FIG. 17 is a partially enlarged schematic view of another conductive pad provided by an embodiment of the present disclosure; FIG. 18 is a schematic cross-sectional view of the conductive pad shown in FIG. 17 along a second direction. As illustrated by FIG. 17 and FIG. 18, each of the plurality of conductive pads 200 further includes a fourth sub-pad 260, and the fourth sub-pad 260 is located on a side of the third sub-pad 250 away from the second insulating layer 240, and the material of the fourth sub-pad 260 includes transparent conductive oxide. Therefore, the fourth sub-pad 260 can protect the sub-pads between the fourth sub-pad 260 and the base substrate 100 from oxidation, and the material of the sub-pads between the fourth sub-pad 260 and the base substrate 100 may be conductive metal with better conductivity, so that the conductive pad 200 can have better conductivity. For example, the material of the fourth sub-pad 260 includes indium tin oxide.

For example, in the case where the material of the fourth sub-pad 260 includes transparent conductive oxide, the first sub-pad 210, the second sub-pad 230, and the third sub-pad 250 may be made of metal materials such as copper, aluminum, titanium, silver, and the like. For example, the first sub-pad 210, the second sub-pad 230 and the third sub-pad 250 may be formed in single-layer structures or multi-layer structures. Embodiments of the present disclosure are not limited thereto.

For example, as illustrated by FIG. 17 and FIG. 18, in the case where the material of the fourth sub-pad 260 includes transparent conductive oxide, the fourth sub-pad 260 can protect the sub-pads between the fourth sub-pad 260 and the base substrate 100 from oxidation, so that, in the present embodiment, the ratio of the size of the first via 221 in the second direction Y to the size of the first via 221 in the first direction X is not limited, and the ratio of the size of the second via 241 in the second direction Y to the size of the second via in the first direction X is not limited. FIG. 17 and FIG. 18 show that the ratios of the sizes of the first via 221 and the second via 241 in the second direction Y to the sizes of the first via 221 and the second via 241 in the first direction X are greater than 5, however, the ratios may also be less than or equal to 5, which is not repeated here.

In some examples, as illustrated by FIGS. 7 to 18, the first insulating layer 220 includes at least one first via 221, and the first via 221 extends along the second direction Y. The size of the first via 221 in the second direction Y is larger than the size of the first via 221 in the first direction X. For example, the conductive material in or around the first via 221 is partially oxidized, the first via 221 with a larger area can reduce the influence of the oxidation of the conductive material on the conductive performance of the conductive pad 200, so that the display substrate can have a better and more stable display effect.

In some examples, as illustrated by FIGS. 7 to 18, the ratio of the size of the first via 221 in the second direction Y to the size of the first via 221 in the first direction X may be any value greater than or equal to 5. For example, the ratio of the size of the first via 221 in the second direction Y to the size of the first via 221 in the first direction X may be greater than or equal to 10, for example, may also be greater than or equal to 18, for example, may also be greater than or equal to 25. According to the size design of different conductive pads 200, the ratio of the size of the first via 221 in the second direction Y to the size of the first via 221 in the first direction X may be designed to have different values.

In some examples, as illustrated by FIGS. 7 to 18, the number of the first vias 221 may be any positive integer greater than or equal to 1, and the number of the first vias 221 may be designed to have different values according to the size design of different the conductive pads 200.

In some examples, as illustrated by FIGS. 7 to 18, the ratio of the area of the orthographic projection of at least one first via 221 on the base substrate 100 to the area of the orthographic projection of the first sub-pad 210 on the base substrate 100 is greater than or equal to 0.5. Therefore, the larger the ratio of the area of the orthographic projection of at least one first via 221 in the first insulating layer 220 on the base substrate 100 to the area of the orthographic projection of the first sub-pad 210 of the conductive pad 200 on the base substrate 100, the larger the area of the first via 221, so that the influence of oxidation of conductive materials on the conductive performance of the conductive pad 200 can be reduced.

For example, in the case where the first insulating layer 220 of each of the plurality of conductive pads 200 include one first via 221, the ratio of the area of the orthographic projection of the one first via 221 on the base substrate 100 to the area of the orthographic projection of the first sub-pad 210 of the conductive pad 200 on the base substrate 100 is greater than or equal to 0.5. For example, in the case where the first insulating layer 220 of each of the plurality of conductive pads 200 includes a plurality of first vias 221, the ratio of the total area of orthographic projections of the plurality of first vias 221 on the base substrate 100 to the area of orthographic projection of the first sub-pad 210 of the conductive pad 200 on the base substrate 100 is greater than or equal to 0.5. For example, the ratio of the areas may be greater than or equal to 0.8. For example, the ratio of the areas may be 0.5, 0.55, 0.6, 0.65, 0.7, 0.75, 0.8, 0.85, 0.9, 0.95, 0.98, 0.99, etc., which are not listed here. According to the size design of different conductive pads 200, the ratio of the area of the orthographic projection of the at least one first via 221 in the first insulating layer 220 on the base substrate 100 to the area of the orthographic projection of the first sub-pad 210 on the base substrate 100 may be designed to have different values.

In some examples, as illustrated by FIGS. 7 to 18, the ratio of the size of at least one first via 221 in the first direction X to the size of the first sub-pad 210 in the first direction X is greater than or equal to 0.5. Therefore, the larger the ratio of the size of the first via 221 in the first direction X to the size of the first sub-pad 210 in the first direction X, the larger the size and area of the first via 221. For example, the conductive material in the first via 221 or around the first via 221 is partially oxidized, and the first via 221 with a larger size and a larger area can reduce the influence of the oxidation of the conductive material on the conductive performance of the conductive pad 200, so that the display substrate can have a better and more stable display effect.

For example, the ratio of the size of the first via 221 in the first direction X to the size of the first sub-pad 210 in the first direction X may be 0.5, 0.65, 0.7, 0.75, 0.8, 0.85, 0.9, 0.95, 0.98, 0.99, 1, etc., which are not listed here.

For example, the ratio of the size of the first via 221 in the first direction X to the size of the first sub-pad 210 in the first direction X and the ratio of the size of the first via 221 in the second direction Y to the size of the first via 221 in the first direction X may all be selected as relatively large values. For example, the ratio of the size of the first via 221 in the first direction X to the size of the first sub-pad 210 in the first direction X may be greater than 0.8, and at the same time, the ratio of the size of the first via 221 in the second direction Y to the size of the first via 221 in the first direction X may be greater than 10, so that the first via 221 can have a larger size and a larger area.

In some examples, as illustrated by FIGS. 8, 10 to 18, the first insulating layer 200 includes only one first via 221. Therefore, the size of the only one first via 221 in the first insulating layer 220 in the second direction Y can be maximized, and the area of the first sub-pad 210 exposed by the first via 221 can be maximized. For example, the ratio of the size of the first via 221 in the second direction Y to the size of the first sub-pad 210 in the second direction Y ranges from 0.7 to 1.0. For example, the ratio of the sizes may be 0.7, 0.75, 0.8, 0.85, 0.9, 0.95, 0.98, 0.99, 1, etc.

For example, the ratio of the size of the first via 221 in the second direction Y to the size of the first sub-pad 210 in the second direction Y may be 0.7, 0.75, 0.8, 0.85, 0.9, 0.95, 0.98, 1, etc., which are not listed here.

For example, as illustrated by FIGS. 8, 10 to 18, the second insulating layer 240 includes only one second via 241, and the first insulating layer 220 includes only one first via 221. For example, in the case where the second insulating layer 240 includes only one second via 241, the ratio of the size of the second via 241 in the second direction Y to the size of the second sub-pad 230 in the second direction Y is greater than or equal to 0.7. For example, in the case where the first insulating layer 220 includes only one first via 221, the ratio of the size of the first via 221 in the second direction Y to the size of the first sub-pad 210 in the second direction Y is greater than or equal to 0.7. Thus, the size of the only one second via 241 in the second direction Y can be maximized, and the size of the only one first via 221 in the second direction Y can be maximized. Therefore, in the case where the conductive material of the conductive pad is oxidized, the influence of the oxidation of the conductive material on the conductive performance of the conductive pad 200 can be reduced through the first via 221 and the second via 241 with larger areas.

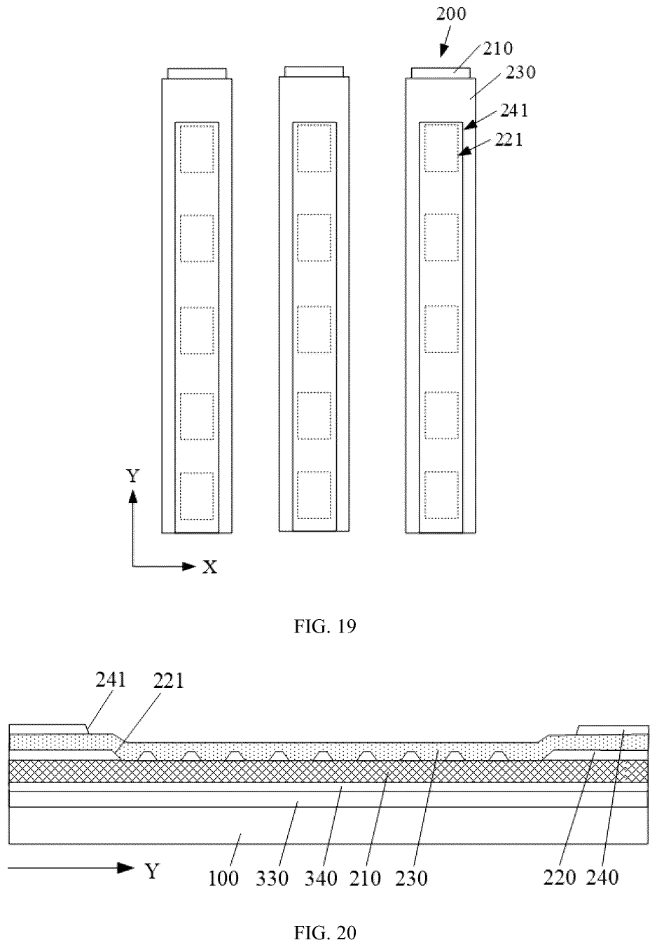

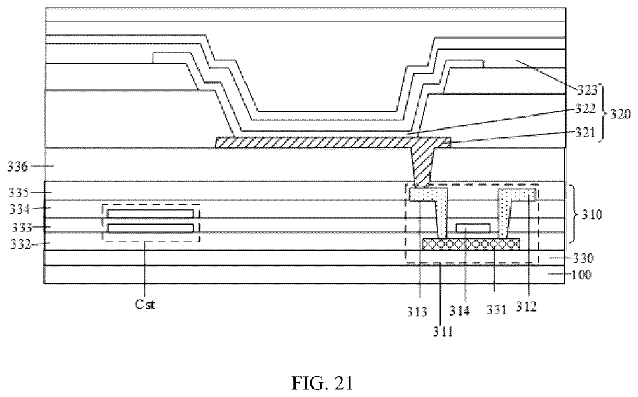

FIG. 19 is a partially enlarged schematic view of another conductive pad provided by an embodiment of the present disclosure; FIG. 20 is a schematic cross-sectional view of the conductive pad shown in FIG. 19 along a second direction. As illustrated by FIGS. 19 and 20, the first insulating layer 220 includes a plurality of first vias 221, the plurality of first vias 221 are arranged along the second direction Y. The ratio of the size of the first via 221 in the second direction Y to the size of the first via 221 in the first direction X is less than or equal to 2, and the second sub-pad 230 can be directly connected with the first sub-pad 210 through the plurality of first vias 221.

It should be noted that the embodiments of the present disclosure do not limit the ratio of the size of the first via 221 in the second direction Y to the size of the first via 221 in the first direction X. For example, as illustrated by FIGS. 7 to 19, it is shown schematically that the ratio of the size of the first via 221 in the second direction Y to the size of the first via 221 in the first direction X is greater than 5; however, the ratio of the size of the first via 221 in the second direction Y to the size of the first via 221 in the first direction X may also be smaller than or equal to 5, which is not repeated herein.

For example, as illustrated by FIG. 19, the second insulating layer 240 includes only one second via 241, and the first insulating layer 220 includes a plurality of first vias 221. For example, in the case where the second insulating layer 240 includes only one second via 241, the ratio of the size of the second via 241 in the second direction Y to the size of the second sub-pad 230 in the second direction Y is greater than or equal to 0.7. Therefore, in the case where the conductive material of the conductive pad is oxidized, the influence of the oxidation of the conductive material on the conductive performance of the conductive pad 200 can be reduced through the second via 241 with a larger area.

FIG. 21 is a schematic cross-sectional view of a display substrate provided by an embodiment of the present disclosure. As illustrated by FIG. 6 and FIG. 21, the display substrate further includes a plurality of pixel units. The plurality of pixel units are located in the display region 101, and each of the plurality of pixel units includes a pixel driving circuit 310 and a light emitting element 320, the pixel driving circuit 310 is located on the base substrate 100, and the light emitting element 320 is located on a side of the pixel driving circuit 310 away from the base substrate 100, and the pixel driving circuit 310 is configured to drive the light emitting element 320 to emit light. For example, the display substrate also includes an encapsulation layer, a touch layer and the like, which are not shown and described in detail here.

For example, the pixel driving circuit 310 may include a transistor 311, a storage capacitor Cst, etc., and may be of various types, such as 2T1C type (i.e., including two transistors 311 and a storage capacitor Cst), and may further include more transistors and/or capacitors based on the 2T1C type to have functions such as compensation, reset, light emission control, detection, etc. The embodiments of the present disclosure do not limit the pixel driving circuit 310. For example, in some embodiments, the transistor 311 directly electrically connected with the light emitting element 320 may be a driving transistor 311 or a light emitting control transistor 311, etc.

As illustrated by FIG. 21, each of the plurality of pixel units further includes a buffer layer 330 on the base substrate 100. The pixel driving circuit 310 includes an active layer 331 located on a side of the buffer layer 330 away from the base substrate 100, a first gate insulating layer 332 located on a side of the active layer 331 away from the base substrate 100, a gate electrode 314 on the first gate insulating layer 332, a second gate insulating layer 333 located on a side of the gate electrode 314 away from the base substrate 100, an interlayer insulating layer 334 located on the second gate insulating layer 333, and a first electrode 312 and a second electrode 313 located on the interlayer insulating layer 334. For example, the first electrode 312 may be a source electrode, and the second electrode 313 may be a drain electrode, and vice versa. A side of the first electrode 312 and the second electrode 313 away from the base substrate 100 is also provided with a passivation layer 335, and a side of the passivation layer 335 away from the base substrate 100 is also provided with a planarization layer 336. A side of the planarization layer 336 away from the base substrate 100 is also provided a first electrode 321, and a side of the first electrode 321 away from the base substrate 100 is also provided with a light emitting material 322 and a second electrode 323. For example, the first electrode 321 may be an anode and the second electrode 323 may be a cathode.

In the embodiments of the present disclosure, the transistor 311 includes the first electrode 312, the second electrode 313 and the gate electrode 314, the gate electrode 314 and the first sub-pad 210 are located in the same conductive layer, and the first electrode 312 and the second electrode 313 are located in the same conductive layer as the second sub-pad 230. Each of the light emitting elements includes the first electrode 321, the light emitting material 322 and the second electrode 323, and the third sub-pad 250 is located in the same conductive layer as the first electrode 321. The case that the gate electrode 314 and the first sub-pad 210 are located in the same conductive layer refers to that the gate electrode 314 and the first sub-pad 210 are formed by the same conductive material layer through the same patterning process, and the case that the first electrode 312 and the second electrode 313 are located in the same conductive layer as the second sub-pad 230 refers to that the first electrode 312, the second electrode 313 and the second sub-pad 230 are formed by the same conductive material layer through the same patterning process, and the case that the third sub-pad 250 and the first electrode 321 are located in the same conductive layer refers to that the third sub-pad 250 and the first electrode 321 are formed by the same conductive material layer through the same patterning process. For example, the first insulating layer 220 of the bonding region 1020 includes a first sub-insulating layer arranged in the same layer as the first insulating layer 220 of the display region 101 and a second sub-insulating layer arranged in the same layer as the interlayer insulating layer 334. For example, the second insulating layer 240 of the bonding region 1020 includes a third sub-insulating layer arranged in the same layer as the passivation layer 335 in the display region 101 and a fourth sub-insulating layer arranged in the same layer as the planarization layer 336 in the display region 101. Of course, the embodiments of the present disclosure are not limited thereto. Using the same conductive material layer through the same patterning process to form each film layer can simplify the preparation process without increasing the process steps, and reduce the preparation cost of the product.

In some examples, as illustrated by FIG. 21, in the case where the light emitting mode of the display panel is the bottom emission type, the material of the conductive layer where the third sub-pad 250 of the conductive pad 200 and the first electrode 321 of the display region 101 are located is a transparent conductive oxide layer. Therefore, the third sub-pad 250 can prevent the first sub-pad 210 and the second sub-pad 230 from being oxidized, the conductive pad 200 can have better conductivity, and the display substrate can have a better and more stable display effect.

In some examples, as illustrated by FIG. 21, in the case where the light emitting mode of the display substrate is the top emission type, the material of the conductive layer where the third sub-pad 250 of the conductive pad 200 and the first electrode 321 of the display region 101 are located may be a three-layer structure. In the case where the materials of the three-layer structure are respectively a transparent conductive oxide layer, a conductive metal layer and a transparent conductive oxide layer, the middle conductive metal layer is used to reflect the light emitted by the light emitting material 322, which is emitted to the external environment through the second electrode 323. In this example, the transparent conductive oxide layer close to the second electrode 323 is thin, so that the conductive metal layer will be at least partially oxidized, and the third sub-pad 250 of the conductive pad 200 will fall off in serious cases. Therefore, the larger area of the second via 241 can reduce the phenomenon of poor lapping connection or no lapping connection between the flexible printed circuit board and the conductive pad 200, so that even if the third sub-pad 250 falls off, the flexible printed circuit board can better and more easily overlap with the conductive pad, so that the display substrate can have a better and more stable display effect.

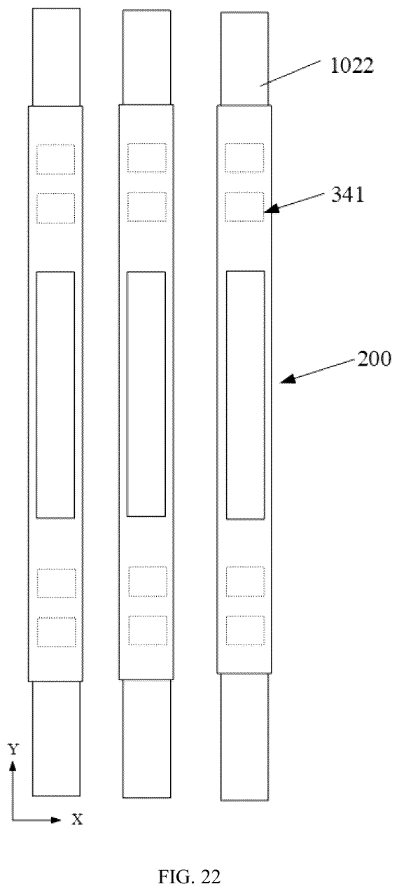

FIG. 22 is a partially enlarged schematic diagram of a bonding region provided by an embodiment of the present disclosure. As illustrated by FIG. 22, the conductive pad 200 includes the conductive pad 200 in any of the above embodiments, and will not be described here again. The conductive pad 200 is connected to a lead 1022 through a via 341. For example, one end of the lead 1022 is connected to a signal line such as the data line 1011 in the display region 101 shown in FIG. 6. For example, the other end of the lead 1022 is connected to a screen lighting device, so that the lead 1022 can be used for detecting a screen. It should be noted that the end of the lead 1022 connected to the screen lighting device can be cut off after screen detection, and can be used only for screen lighting detection in the testing stage.

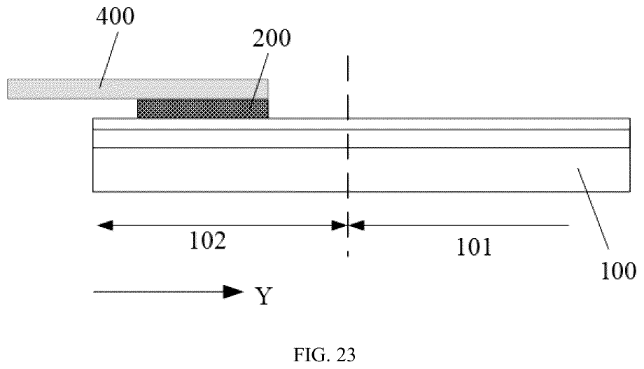

FIG. 23 is a schematic cross-sectional view of a conductive pad connected to a flexible printed circuit board according to an embodiment of the present disclosure. As illustrated by FIG. 23, the flexible printed circuit board 400 is connected to the display substrate through the conductive pad 200, so that the driving circuit board can transmit the display data to the display substrate through the flexible printed circuit board 400 to drive the display substrate to perform light emitting display. The conductive pad 200 includes the conductive pad 200 in any of the above embodiments, and will not be described in detail here.

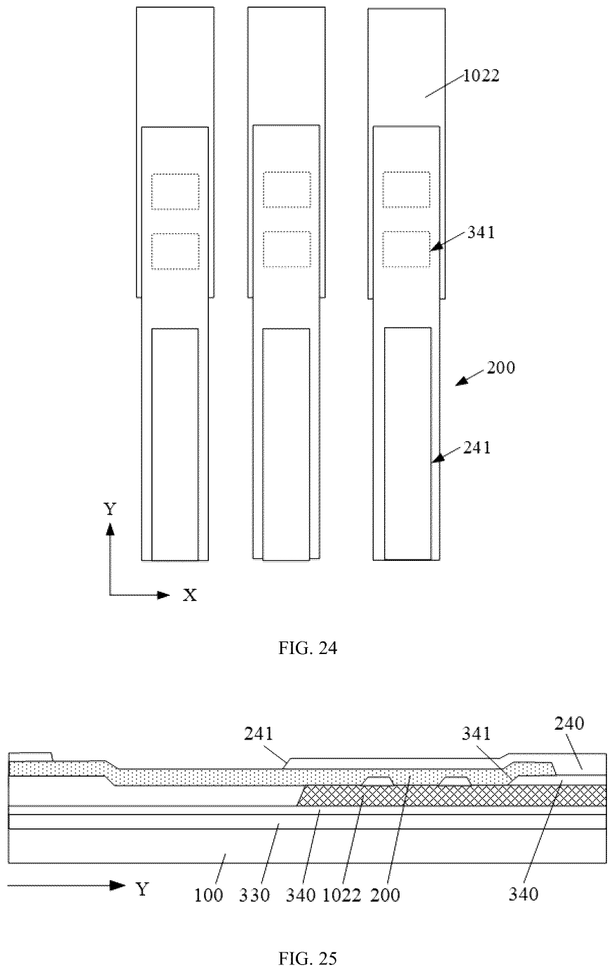

FIG. 24 is a partially enlarged schematic view of another conductive pad provided by an embodiment of the present disclosure; FIG. 25 is a schematic cross-sectional view of the conductive pad shown in FIG. 24 along a second direction. As illustrated by FIG. 6, FIG. 24 and FIG. 25, a plurality of conductive pads 200 of the display substrate are arranged along a first direction X, and each of the plurality of conductive pads 200 is located on the base substrate 100 and extends along a second direction Y. For example, the material of each of the plurality of conductive pads 200 includes a conductive material that is not easily oxidized, and the flexible printed circuit board can be connected with the conductive pad 200 to realize the connection with the display substrate.

For example, as illustrated by FIG. 24 and FIG. 25, the conductive pad 200 may have a single-layer structure. Of course, the embodiments of the present disclosure are not limited thereto. For example, the material of the conductive pad 200 may be a stacked structure. For example, the stacked structure of the conductive pad 200 may be a three-layer structure, which includes a first protective layer, a conductive metal layer and a second protective layer, respectively. The conductive metal layer is located between the first protective layer and the second protective layer, the first protective layer is closer to the base substrate 100 than the second protective layer, and the material of the second protective layer may include a conductive material that is not easy to be oxidized, so as to protect the conductive metal layer. The embodiments of the present disclosure do not limit the specific material of the conductive pad 200.

In some examples, as illustrated by FIG. 25, a side of the conductive pad 200 away from the base substrate 100 is also provided with an insulating layer 240, and the insulating layer 240 is provided with a via 241, and an orthographic projection of the via 241 on the base substrate 100 falls within an orthographic projection of the conductive pad 200 on the base substrate 100, so that the flexible printed circuit board can directly contact the conductive pad 200 through the via 241 to realize the connection with the display substrate. The insulating layer 240 may cover at least part of the edges or lateral sides of the conductive pad 200, for example, the insulating layer 240 may cover the edges or lateral sides of the conductive pad 200 extending in the first direction X and the second direction Y, so that the insulating layer 240 can protect the edges or lateral sides of the conductive pad 200. For example, the edges or lateral sides of the conductive pad 200 can be prevented from being oxidized.

In some examples, as illustrated by FIG. 24 and FIG. 25, the conductive pad 200 and the lead 1022 are located in different conductive layers, and the conductive pad 200 is connected with the lead 1022 through a via 341. The insulating layer 240 is located on a side of the lead 1022 away from the base substrate 100, which can also avoid the scratch of the lead 1022 and other undesirable phenomena.

It should be noted that in order to clearly show the conductive pads 200, the insulating layer 240 in FIG. 24 only shows the vias 241, and the sizes of the conductive pads 200 and the vias 241 in FIG. 24 in the second direction Y are only partially shown. It is also schematic that the sizes of the conductive pads 200 in the first direction X are smaller than the sizes of the leads 1022 in the first direction X, and the sizes of the conductive pads 200 in the first direction X may also be larger than the sizes of the leads 1022 in the first direction X, which is not limited in the embodiments of the present disclosure.

In some examples, as illustrated by FIG. 6, FIG. 21 and FIG. 25, the gate electrode 314 and the lead 1022 are located in the same conductive layer, and the first electrode 312 and the second electrode 313 are located in the same conductive layer as the conductive pad 200. The case that the gate electrode 314 and the lead 1022 are located in the same conductive layer refers to that the gate electrode 314 and the lead 1022 are formed by the same conductive material layer through the same patterning process, and the case that the first electrode 312 and the second electrode 313 are located in the same conductive layer as the conductive pad 200 refers to that the first electrode 312, the second electrode 313 and the conductive pad 200 are formed by the same conductive material layer through the same patterning process. Of course, the embodiments of the present disclosure are not limited thereto. Using the same conductive material layer through the same patterning process to form each film layer can simplify the preparation process without increasing the process steps, and reduce the preparation cost of the product.

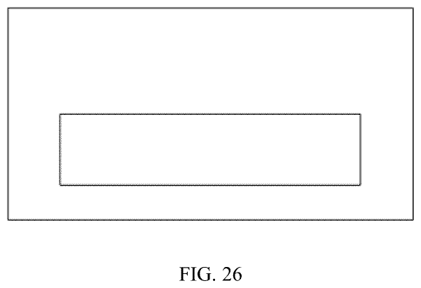

An embodiment of the present disclosure further provides a display device. FIG. 26 is a schematic diagram of a display device provided by an embodiment of the present disclosure. As illustrated by FIG. 26, the display device includes the display substrate in any of the above embodiments. Therefore, the display device has the beneficial effects corresponding to the beneficial effects of the display substrate, which are not described in detail here.

For example, the display device may be a TV, a computer monitor, a notebook computer, a tablet computer, a smart phone, a navigator, an electronic picture frame, a vehicle-mounted display and the like.

The following statements should be noted:
(1) The drawings involve only the structure(s) in connection with the embodiment(s) of the present disclosure, and other structure(s) can be referred to common design(s).
(2) In case of no conflict, features in one embodiment or in different embodiments can be combined to obtain new embodiments.

The above is only the specific embodiment of the present disclosure, but the protection scope of the present disclosure is not limited thereto. Any person familiar with the technical field can easily think of changes or substitutions within the technical scope disclosed in the present disclosure, and they should be included in the protection scope of the present disclosure. Therefore, the scope of protection of the present disclosure should be based on the scope of protection of the claims.

1. A display substrate comprising:
a base substrate, comprising a display region and a peripheral region at least partially surrounding the display region; and
a plurality of conductive pads, in a bonding region, wherein the bonding region is in the peripheral region, the plurality of conductive pads are arranged along a first direction, and each of the plurality of conductive pads extends along a second direction intersecting the first direction, and comprises:
a first sub-pad, on the base substrate;
a first insulating layer, on a side of the first sub-pad away from the base substrate;
a second sub-pad, on a side of the first insulating layer away from the first sub-pad;
a second insulating layer, on a side of the second sub-pad away from the first insulating layer;
a first via, penetrating the first insulating layer, and the second sub-pad being directly connected with the first sub-pad through the first via; and
a second via, penetrating the second insulating layer to expose a part of the second sub-pad,
wherein at least one first via is provided between the first sub-pad and a corresponding second sub-pad, an orthographic projection of the first via on the base substrate overlaps with an orthographic projection of at least one second via on the base substrate, and at least one second via has a size in the second direction being larger than a size in the first direction.

2. The display substrate according to claim 1, wherein a ratio of the size of the second via in the second direction to the size of the second via in the first direction is greater than or equal to 5.

3. The display substrate according to claim 1, wherein a ratio of an area of the orthographic projection of the at least one second via on the base substrate to an area of an orthographic projection of the second sub-pad on the base substrate is greater than or equal to 0.5.

4. The display substrate according to claim 1, wherein a ratio of the size of the at least one second via in the first direction to a size of the second sub-pad in the first direction is greater than or equal to 0.5.

5. The display substrate according to claim 1, wherein a ratio of the size of the at least one second via in the second direction to a size of the second sub-pad in the second direction is greater than or equal to 0.7.

6. The display substrate according to claim 1, wherein an orthographic projection of the second via on the base substrate covers the orthographic projection of the first via on the base substrate.

7. The display substrate according to claim 1, wherein each of the plurality of conductive pads further comprises:
a third sub-pad, on a side of the second insulating layer away from the second sub-pad,
wherein the third sub-pad is directly connected with the second sub-pad through the second via.

8. The display substrate according to claim 7, wherein the third sub-pad comprises:
a first sub-layer, at least partially located in the second via and directly connected with the second sub-pad; and
an oxide, at a periphery of the second via, in the second via, or on a side of the first sub-layer away from the second sub-pad,
wherein a material of the first sub-layer comprises a transparent conductive oxide.

9. The display substrate according to claim 8, wherein the first sub-layer comprises at least one opening, and an orthographic projection of the opening on the base substrate falls within an orthographic projection of the second via on the base substrate.

10. The display substrate according to claim 8, wherein the third sub-pad further comprises:
a second sub-layer, on a side of the first sub-layer away from the second sub-pad,
wherein a material of the second sub-layer comprises a conductive metal, and the oxide comprises an oxide of the conductive metal.

11. The display substrate according to claim 10, wherein the third sub-pad further comprises a third sub-layer, at least partially located on a side of the second sub-layer away from the second sub-pad,
a material of the third sub-layer comprises a transparent conductive oxide.

12. The display substrate according to claim 7, wherein each of the plurality of conductive pads further comprises:
a fourth sub-pad, on a side of the third sub-pad away from the second insulating layer,
wherein a material of the fourth sub-pad comprises a transparent conductive oxide.

13. The display substrate according to claim 1, wherein a size of the first via in the second direction is larger than a size of the first via in the first direction.

14. The display substrate according to claim 13, wherein a ratio of the size of the first via in the second direction to the size of the first via in the first direction is greater than or equal to 5.

15. The display substrate according to claim 14, wherein a ratio of an area of an orthographic projection of at least one first via on the base substrate to an area of an orthographic projection of the first sub-pad on the base substrate is greater than or equal to 0.5.

16. The display substrate according to claim 14, wherein a ratio of a size of at least one first via in the first direction to a size of the first sub-pad in the first direction is greater than or equal to 0.5.

17. (canceled)

18. (canceled)

19. The display substrate according to claim 1, wherein the second insulating layer comprises only one second via, and a ratio of a size of the second via in the second direction to a size of the second sub-pad in the second direction is greater than or equal to 0.7,
the first insulating layer comprises only one first via, and a ratio of a size of the first via in the second direction to a size of the first sub-pad in the second direction is greater than or equal to 0.7.

20. The display substrate according to claim 1, wherein the second insulating layer comprises only one second via, and a ratio of a size of the second via in the second direction to a size of the second sub-pad in the second direction is greater than or equal to 0.7,
the first insulating layer comprises a plurality of first vias.

21. The display substrate according to claim 7, further comprising:
a plurality of pixel units, in the display region,
wherein each of the plurality of pixel units comprises a pixel driving circuit and a light emitting element, the pixel driving circuit is on the base substrate, and the light emitting element is on a side of the pixel driving circuit away from the base substrate, and the pixel driving circuit is configured to drive the light emitting element to emit light,
the pixel driving circuit comprises a transistor, the transistor comprises a first electrode, a second electrode and a gate electrode, the gate electrode and the first sub-pad are in a same conductive layer, and the first electrode and the second electrode are in a same conductive layer;
the light emitting element comprises a first electrode and a second electrode, the third sub-pad and the first electrode of the light emitting element are in a same conductive layer, and the second electrode of the light emitting element is on a side of the first electrode of the light emitting element away from the base substrate.

22. A display device, comprising the display substrate according to claim 1.
